(19) United States
(12) Patent Application Publication
(10) Pub. No.: US 2026/0089974 A1
(43) Pub. Date: Mar. 26, 2026

(54) FERROELECTRIC MEMORY DEVICE

(71) Applicant: Samsung Electronics Co., Ltd., Suwon-si (KR)

(72) Inventors: Sihyun Kim, Seoul (KR); Heebum Kang, Seoul (KR)

(73) Assignees: Samsung Electronics Co., Ltd., Suwon-si (KR); Sogang University Research Foundation, Seoul (KR)

(21) Appl. No.: 19/214,356

(22) Filed: May 21, 2025

(30) Foreign Application Priority Data
Sep. 20, 2024 (KR) 10-2024-0127683

(51) Int. Cl. H10B 53/30; G11C 5/06; H10B 53/10; H10D 1/68; H10D 64/01; H10D 64/68

(52) U.S. Cl. CPC H10B 53/30; G11C 5/063; H10B 53/10; H10D 1/714; H10D 1/716; H10D 64/033; H10D 64/689

(57) ABSTRACT

A ferroelectric memory device includes a cylindrical channel layer in a channel hole, a gate insulating layer on the cylindrical channel layer, an inner gate electrode in the channel hole and on the gate insulating layer, a spacer on the inner gate electrode and on an inner wall of a recess hole, where the recess hole extends in a vertical direction from an upper surface towards the bottom of the cylindrical channel layer, a ferroelectric layer on the spacer and on the inner gate electrode, a control gate electrode in the recess hole and on the ferroelectric layer opposite the inner gate electrode, a first source and drain layer extending around a lower portion of the cylindrical channel layer, and a second source and drain layer spaced apart from the first source and drain layer in the vertical direction, and extending around an upper portion of the cylindrical channel layer.

### CROSS-REFERENCE TO RELATED APPLICATION

This application is based on and claims priority under 35 U.S.C. § 119 to Korean Patent Application No. 10-2024-0127683, filed on Sep. 20, 2024, in the Korean Intellectual Property Office, the disclosure of which is incorporated by reference herein in its entirety.

### TECHNICAL FIELD

The inventive concept relates to a memory device, and more particularly, to a ferroelectric memory device.

### BACKGROUND

Ferroelectric materials or ferroelectrics are materials with ferroelectricity in which internal dipole moments align and maintain spontaneous polarization even when no external electric field is applied thereto. Ferroelectric materials may exhibit hysteresis characteristics in electrical polarization when an external electric field is applied thereto.

A ferroelectric is a material in which, even if the voltage is brought back to 0 V after applying a certain voltage, the remanent polarization remains semi-permanently within the material. Ferroelectric memory devices in which ferroelectrics are used as gate insulating layers (or gate dielectric layers) are being researched. A memory window may refer to the maximum range of operating voltages that may be applied to record distinct remanent polarizations in a gate insulating layer formed of a ferroelectric layer in a ferroelectric memory device.

### SUMMARY

The inventive concept provides a ferroelectric memory device which may improve a memory window and increase endurance or durability.

According to an aspect of the inventive concept, there is provided a ferroelectric memory device including a cylindrical channel layer in a channel hole, a gate insulating layer on an inner wall and a bottom of the cylindrical channel layer, an inner gate electrode in the channel hole and on the gate insulating layer, a spacer on the inner gate electrode and on an inner wall of a recess hole, where the recess hole extends in a vertical direction from an upper surface towards the bottom of the cylindrical channel layer, a ferroelectric layer on a side surface and an upper surface of the spacer and on the inner gate electrode, a control gate electrode in the recess hole and on the ferroelectric layer opposite the inner gate electrode, a first source and drain layer extending around a lower portion of the cylindrical channel layer, and a second source and drain layer spaced apart from the first source and drain layer in the vertical direction, and extending around an upper portion of the cylindrical channel layer.

According to another aspect of the inventive concept, there is provided a ferroelectric memory device including a cylindrical channel layer in a channel hole, a gate insulating layer on an inner wall and a bottom of the cylindrical channel layer, an inner gate electrode in the channel hole and on the gate insulating layer, a spacer on the inner gate electrode and on an inner wall of a recess hole, where the recess hole extends in a vertical direction from an upper surface towards the bottom of the cylindrical channel layer, a ferroelectric layer on a side surface and an upper surface of the spacer and on the inner gate electrode, a control gate electrode in the recess hole and on the ferroelectric layer opposite the inner gate electrode, a first source and drain layer extending around a lower portion of the cylindrical channel layer, and a second source and drain layer spaced apart from the first source and drain layer in the vertical direction and extending around an upper portion of the cylindrical channel layer, where the control gate electrode, the ferroelectric layer, and the inner gate electrode include a horizontal capacitor, where the inner gate electrode, the gate insulating layer, and the cylindrical channel layer include a vertical capacitor, and where the horizontal capacitor is electrically connected in series to the vertical capacitor.

According to another aspect of the inventive concept, there is provided a ferroelectric memory device including a plurality of word lines extending in a first horizontal direction and spaced apart from each other in a second horizontal direction perpendicular to the first horizontal direction, a plurality of first source and bit lines below the plurality of word lines in a vertical direction, extending in the second horizontal direction, and spaced apart from each other in the first horizontal direction, a plurality of second source and bit lines between the plurality of word lines and the plurality of first source and bit lines in the vertical direction, extending in the second horizontal direction, and spaced apart from each other in the first horizontal direction, and a plurality of vertical channel structures in a plurality of intersection areas, respectively, where the plurality of intersection areas each include an area of overlap between the plurality of word lines, the plurality of first source and bit lines, and the plurality of second source and bit lines.

Each of the plurality of vertical channel structures includes a cylindrical channel layer in a channel hole, a gate insulating layer on an inner wall and a bottom of the cylindrical channel layer, an inner gate electrode on the gate insulating layer, a spacer on the inner gate electrode and on an inner wall of a recess hole, where the recess hole extends in a vertical direction from an upper surface towards the bottom of the cylindrical channel layer, a ferroelectric layer on a side surface and an upper surface of the spacer and on the inner gate electrode, a control gate electrode in the recess hole, on the ferroelectric layer opposite the inner gate electrode, and electrically connected to a respective word line of the plurality of word lines, a first source and drain layer extending around a lower portion of the cylindrical channel layer and connected to a respective first source and bit line of the plurality of first source and bit lines, and a second source and drain layer spaced apart from the first source and drain layer in the vertical direction, extending around an upper portion of the cylindrical channel layer, and connected to a respective second source and bit line of the plurality of second source and bit lines.

### BRIEF DESCRIPTION OF THE DRAWINGS

Embodiments of the inventive concept will be more clearly understood from the following detailed description taken in conjunction with the accompanying drawings in which:

FIG. 1 is a layout diagram of a ferroelectric memory device according to some embodiments;

FIG. 2 is a cross-sectional view of the ferroelectric memory device taken along line A-A′ of FIG. 1;

FIG. 3 is a cross-sectional view of the ferroelectric memory device taken along line B-B′ of FIG. 1;

FIG. 4 is a horizontal cross-sectional view of the ferroelectric memory device taken along line C-C′ of FIG. 2;

FIG. 5 is a perspective view of a ferroelectric memory device according to some embodiments;

FIG. 6 is a partially cut-away, enlarged view for illustrating a horizontal capacitor and a vertical capacitor of FIG. 5;

FIG. 7 is an equivalent circuit diagram of the horizontal capacitor and the vertical capacitor of FIG. 5;

FIG. 8 shows a distribution ratio of a gate voltage applied to the control gate electrode of FIG. 7;

FIGS. 9 and 10 are cross-sectional views for illustrating an adjustment of an area of a horizontal capacitor through an adjustment of a thickness of a spacer of a ferroelectric memory device according to some embodiments;

FIGS. 11, 12, 13, 14, 15, 16, and 17 are cross-sectional views for illustrating a method of manufacturing a ferroelectric memory device, according to some embodiments;

FIG. 18 is a cross-sectional view of a ferroelectric memory device according to a comparative example for comparison with a ferroelectric memory device according to some embodiments;

FIG. 19 is a graph for illustrating a memory window of a ferroelectric memory device according to some embodiments; and

FIG. 20 is a cross-sectional view for illustrating a ferroelectric memory device according to some embodiments.

### DETAILED DESCRIPTION

Hereinafter, embodiments are described in detail with reference to the accompanying drawings. Embodiments presented below may be implemented by any one embodiment only, or the embodiments below may be implemented by combining one or more embodiments. Accordingly, the following embodiments should not be construed as limiting the scope of the inventive concept.

The term “first,” “second,” or the like used herein may modify various elements regardless of the order and/or priority thereof, and is used only for distinguishing one element from another element, without limiting example embodiments. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” as used herein, refers to electrical and/or physical connection between elements or components and does not preclude the presence of additional elements or components therebetween. When elements or layers are referred to herein as “directly on” one another, no intervening elements or layers are present.

Spatially relative terms such as “above,” “upper,” “upper portion,” “upper surface,” “below,” “beneath,” “lower,” “lower portion,” “lower surface,” “side surface,” “inner,” “outer,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. An expression used in a singular form in the disclosure also includes the expression in its plural form unless clearly specified otherwise in context. Additionally, the drawings may be exaggerated for convenience of explanation and clarity.

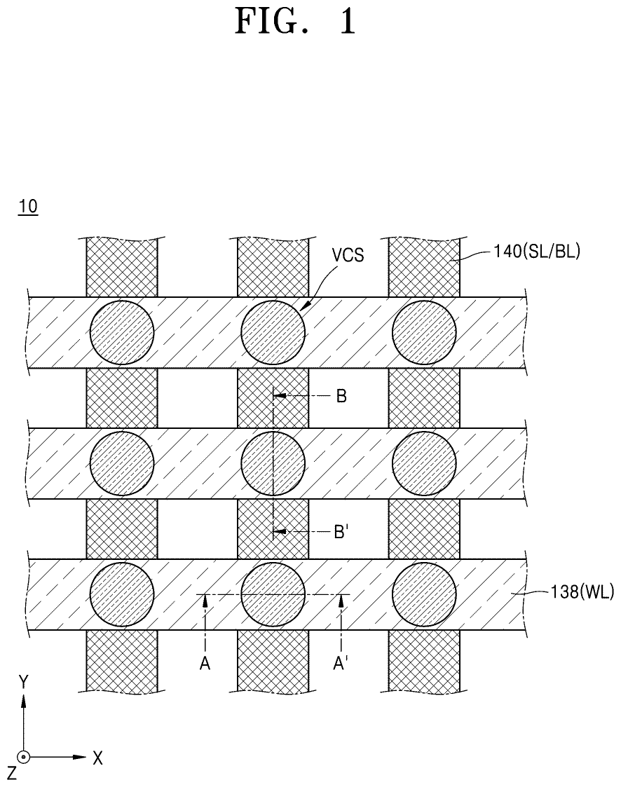

FIG. 1 is a layout diagram of a ferroelectric memory device 10 according to some embodiments.

In detail, the ferroelectric memory device 10 may include a plurality of word lines WL 138 (i.e., 138 (WL), a plurality of source and bit lines SL/BL 140 (also referred to as source/bit lines), and a plurality of vertical channel structures VCS. The ferroelectric memory device 10 may include a ferroelectric electric field effect transistor. The word lines WL 138 extend in a first horizontal direction (e.g., X direction) and are apart from each other in a second horizontal direction (e.g., Y direction) perpendicular to the first horizontal direction.

Source and bit lines SL/BL 140 may include, as described below, first source and bit lines BL/SL and second source and bit lines SL/BL apart from each other in a vertical direction (e.g., Z direction). The second source and bit lines SL/BL may be above the first source and bit lines BL/SL, may extend in the second horizontal direction and may be spaced apart from each other in a horizontal direction (e.g., X direction or Y direction). The vertical channel structures VCS may be arranged in intersection areas, respectively, and the intersection areas may each include an area of overlap between the word lines WL 138 and the source and bit lines SL/BL 140. A vertical structure of the vertical channel structures VCS and the source and bit lines SL/BL 140 is described below in detail. The term “overlap,” when used herein may specify the position of an element as on, in contact with, and/or covering another element. Components or layers described with reference to “overlap” in a particular direction may be at least partially obstructed by one another when viewed along a line extending in the particular direction or in a plane perpendicular to the particular direction.

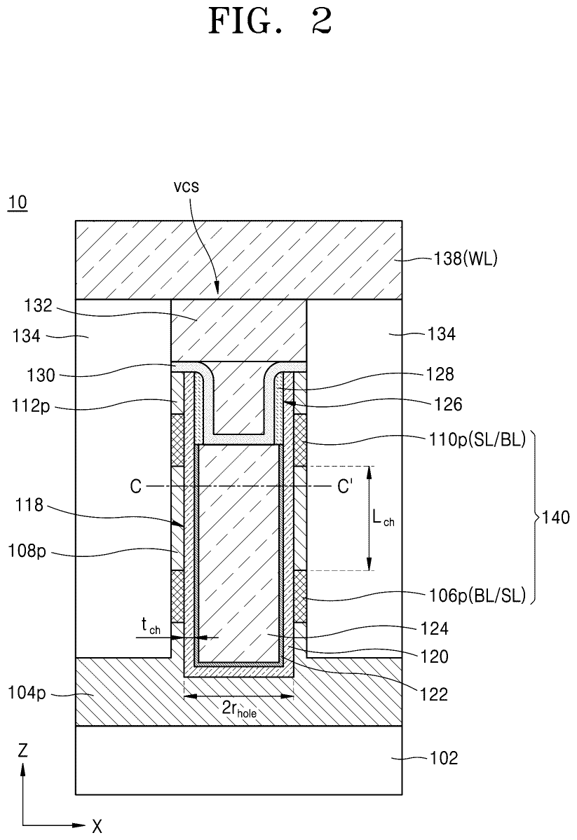

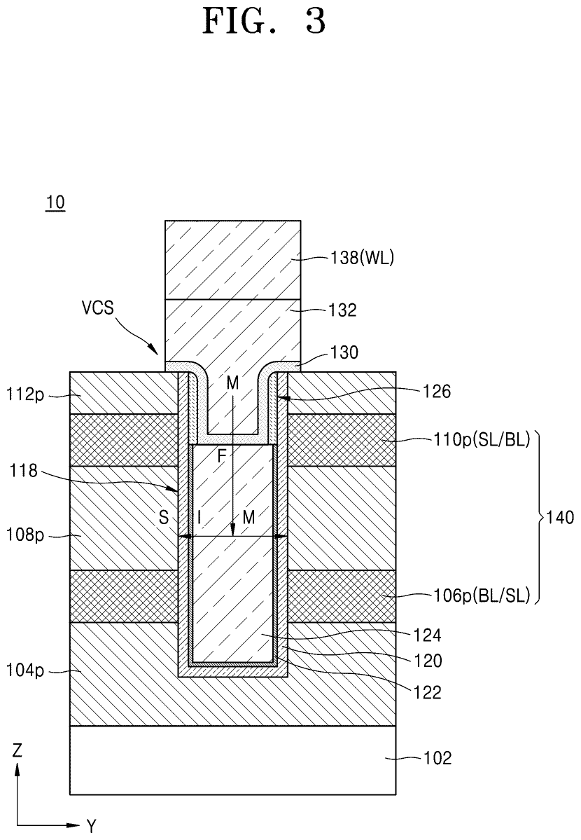

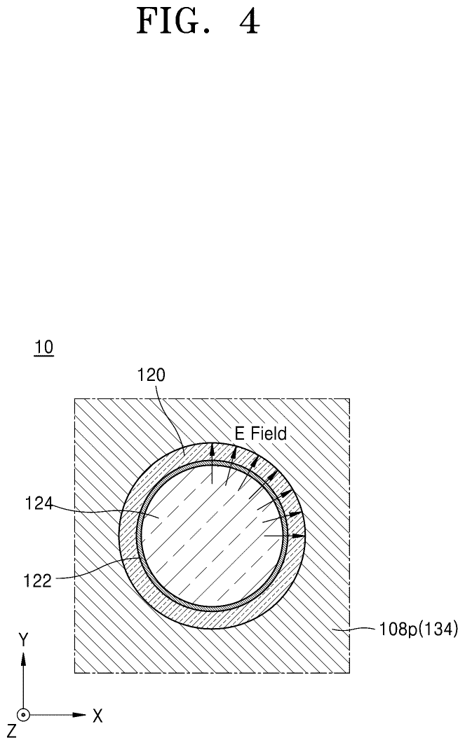

FIG. 2 is a cross-sectional view of the ferroelectric memory device 10 taken along line A-A′ of FIG. 1. FIG. 3 is a cross-sectional view of the ferroelectric memory device 10 taken along line B-B′ of FIG. 1. FIG. 4 is a horizontal cross-sectional view of the ferroelectric memory device 10 taken along line C-C′ of FIG. 2.

In detail, FIG. 2 is a cross-sectional view according to the direction of the word lines WL 138 in FIG. 1. FIG. 3 is a cross-sectional view according to the direction of the source and bit lines SL/BL 140 in FIG. 1. FIG. 4 is a horizontal, cross-sectional view of a cylindrical channel layer 120, a gate insulating layer 122, and an inner gate electrode 124 of FIGS. 2 and 3.

The ferroelectric memory device 10 may include a vertical channel structure VCS arranged on a semiconductor substrate 102. A device isolation insulating layer 134 is arranged on opposite sides of the vertical channel structure VCS. The vertical channel structure VCS may include the cylindrical channel layer 120, the gate insulating layer 122, the inner gate electrode 124, a spacer 128, a ferroelectric layer 130, a control gate electrode 132, a first source and drain layer (also referred to as a first source/drain layer) 106p, and a second source and drain layer (also referred to as a second source/drain layer) 110p.

The cylindrical channel layer 120 may be arranged within a channel hole 118. The channel hole 118 may be formed within a third insulating pattern 112p, the second source and drain layer 110p, a second insulating pattern 108p, the first source and drain layer 106p, and a first insulating pattern 104p.

The cylindrical channel layer 120 may be arranged on the inner wall and the bottom of the channel hole 118. The cylindrical channel layer 120 may have a thickness t_{ch} of several nanometers, for example, 5 nm. The cylindrical channel layer 120 may be a polysilicon layer. In some embodiments, the cylindrical channel layer 120 may be an impurity-doped polysilicon layer.

The gate insulating layer 122 may be arranged on the inner wall and the bottom of the cylindrical channel layer 120 (e.g., lining a portion of the cylindrical channel layer) within the channel hole 118. In some embodiments, the gate insulating layer 122 may be a silicon oxide layer. An inner gate electrode 124 may be formed to fill a part of the channel hole 118 above (i.e., on) the gate insulating layer 122. The term “fill,” “filling,” or the like as used herein, may refer to a process in which an element or component may partially, completely, or over fill a void or cavity.

The inner gate electrode 124 may be formed as a metal layer including, for example, titanium nitride (TiN), titanium (Ti), aluminum (Al), gold (Au), or tungsten (W). As illustrated in FIG. 4, when an operating voltage is applied to the inner gate electrode 124, an electric field may be applied in a radial shape to the gate insulating layer 122 and the cylindrical channel layer 120.

In other words, the ferroelectric memory device 10 includes a channel-all-around structure in which the cylindrical channel layer 120 encompasses the inner gate electrode 124. When an operating voltage is applied to the inner gate electrode 124, an electric field (E-Field) disperses from the center of the inner gate electrode 124 so that an electric field applied to the gate insulating layer 122 may be reduced.

The spacer 128 may be arranged on an inner wall of a recess hole 126 above the inner gate electrode 124, and the recess hole 126 is recessed in a vertical direction from an upper surface to a lower surface of the cylindrical channel layer 120. In other words, the spacer may be on the inner gate electrode and lining a portion of the recess hole. The recess hole 126 may extend into an upper portion of the channel hole. The recess hole 126 may be arranged above the channel hole 118 and inside the cylindrical channel layer 120. The term “recessed” may be used herein to specify a component or layer that is set back or indented relative to a surrounding surface. The recessed component or layer may extend into a space or area to create a depression or lower region relative to the surrounding material or surface and thus the component or layer is positioned lower (i.e., deeper) than the surrounding material or surface.

The spacer 128 may be arranged on the upper surface of the inner gate electrode 124, an upper surface of the gate insulating layer 122, and the inner wall of the cylindrical channel layer 120. The spacer 128 may have a thickness of tens of nanometers or less. In other words, the spacer may have thickness of less than 100 nanometers. In some embodiments, the spacer 128 may be a silicon oxide layer.

The ferroelectric layer 130 may be arranged on a side surface and an upper surface of the spacer 128 (e.g., lining the spacer) and above or on the inner gate electrode 124. The ferroelectric layer 130 may be arranged on the upper surface of the inner gate electrode 124, the side surface and the upper surface of the spacer 128, and an upper surface of the cylindrical channel layer 120. The ferroelectric layer 130 may be arranged above the inner gate electrode 124 and may have a thickness of several nanometers or less.

The ferroelectric layer 130 may include a hafnium oxide (HfO₂), a hafnium silicon oxide (HfSiO), a hafnium zirconium oxide (HfZrO), a hafnium aluminum oxide (HfAlO), etc. In some embodiments, the ferroelectric layer 130 may be a perovskite layer.

The control gate electrode 132 may fill the inside of the recess hole 126 above the ferroelectric layer 130. The control gate electrode 132 may be arranged on the upper surface of the ferroelectric layer 130 inside the recess hole 126, and on the upper surface of the ferroelectric layer 130 formed on the cylindrical channel layer 120. In other words, the control gate electrode 132 may be on the ferroelectric layer.

In some embodiments, the control gate electrode 132 may be formed as a metal layer including, for example, TIN, Ti, Al, Au, or W. In some embodiments, the control gate electrode 132 may be an impurity-doped polysilicon layer.

The first source and drain layer 106p may be arranged to surround a lower portion of the cylindrical channel layer 120. In other words, the first source and drain layer 106p may be on opposite surfaces of a lower portion of the cylindrical channel layer 120. The second source and drain layer 110p may be apart from the first source and drain layer 106p in the vertical direction (e.g., Z direction) and may be arranged to surround an upper portion of the cylindrical channel layer 120. In other words, the second source and drain layer 110p may be spaced apart from the first source and drain layer 106p in the vertical direction. The second source and drain layer 110p may be on opposite surfaces of an upper portion of the cylindrical channel layer 120 and electrically connected to the second source and bit lines SL/BL 140.

The first source and drain layer 106p and the second source and drain layer 110p may each be a metal layer. A length (i.e., distance) of the cylindrical channel layer 120 between the first source and drain layer 106p and the second source and drain layer 110p in the vertical direction (e.g., Z direction) may be a vertical channel length L_{ch}.

The first source and drain layer 106p and the second source and drain layer 110p may constitute the source and bit lines SL/BL 140. The second source and drain layer 110p may be a second source and bit line SL/BL. The first source and drain layer 106p may be a first source and bit line BL/SL.

The ferroelectric memory device 10 may include the word lines WL 138 arranged on the vertical channel structure VCS. The word lines WL 138 may extend in the first horizontal direction (e.g., X direction) and may be apart from each other in the second horizontal direction (e.g., Y direction), as described above. The word lines WL 138 may each be formed as a metal layer including, for example, TiN, Ti, Al, Au, or W.

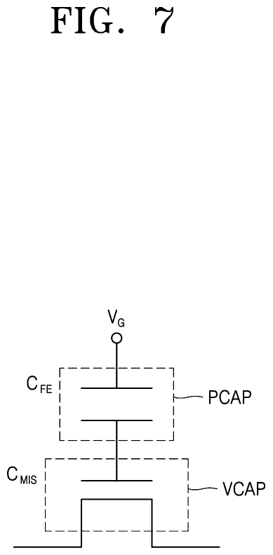

The control gate electrode 132, the ferroelectric layer 130, and the inner gate electrode 124 of the ferroelectric memory device 10 illustrated in FIG. 3 may constitute a horizontal capacitor (PCAP of FIG. 7). In other words, a control gate electrode (Metal layer), a ferroelectric layer (Ferroelectric material layer), and an inner gate electrode (Metal layer) may constitute a horizontal (flat panel type) MFM capacitor (PCAP of FIG. 7).

The inner gate electrode 124, the gate insulating layer 122, and the cylindrical channel layer 120 of the ferroelectric memory device 10 illustrated in FIG. 3 may constitute a vertical capacitor (VCAP of FIG. 7). In other words, an inner gate electrode (Metal layer), a gate insulating layer (gate Insulating layer), and a channel layer (polySilicon layer) may constitute a vertical MIS capacitor (VCAP of FIG. 7). The horizontal capacitor (PCAP of FIG. 7) is connected in series to the vertical capacitor (VCAP of FIG. 7).

A write operation of the ferroelectric memory device 10 may be performed by applying to the control gate electrode 132, a voltage relatively higher than a voltage applied to the first and second source and drain layers 106p and 110p. For example, the write operation may be performed by applying a positive voltage to the control gate electrode 132 and 0 V to the first and second source and drain layers 106p and 110p.

During the write operation, an electric field may be formed in a direction from the control gate electrode 132 to the inner gate electrode 124, and the polarization of the ferroelectric layer 130 may be formed in the same direction. A channel region of the cylindrical channel layer 120 is in accumulation state in which electrons are accumulated to have a low threshold voltage.

An erase operation of the ferroelectric memory device 10 may be performed by applying to the control gate electrode 132, a voltage relatively lower than the voltage applied to the first and second source and drain layers 106p and 110p. For example, the erase operation may be performed by applying a negative voltage to the control gate electrode 132 and 0 V to the first and second source and drain layers 106p and 110p.

During the erase operation, an electric field may be formed in a direction from the inner gate electrode 124 to the control gate electrode 132, and the polarization of the ferroelectric layer 130 may also be formed in the same direction. A depletion area is formed in the channel region of the cylindrical channel layer 120 to have a high threshold voltage.

After the write or erase operation, stored data may be checked by reading a current while applying a read voltage to the control gate electrode 132 and a voltage difference between the first and second source and drain layers 106p and 110p.

In the ferroelectric memory device 10 according to the inventive concept configured as above, the thickness of the spacer 128 formed on the side wall of the cylindrical channel layer 120 may be adjusted. Accordingly, in the ferroelectric memory device 10 of the inventive concept, an operating voltage applied through the control gate electrode 132 may increase a voltage applied to the horizontal MFM capacitor and decrease a voltage applied to the vertical MIS capacitor. Accordingly, the ferroelectric memory device 10 of the inventive concept may increase endurance or durability while improving the memory window.

As no junction area exists in the cylindrical channel layer 120, the ferroelectric memory device 10, as described below, has a simplified manufacturing process and is less affected by a short channel effect (SCE).

As the ferroelectric memory device 10 has, as described above, a channel-all-around structure in which the cylindrical channel layer 120 surrounds the inner gate electrode 124, the electric field disperses from the center of the inner gate electrode 124 to decrease an electric field applied to the gate insulating layer 122 so that durability may be improved. The ferroelectric memory device 10 has a structure in which the first source and drain layer 106p and the second source and drain layer 110p are easily separated from the control gate electrode 132.

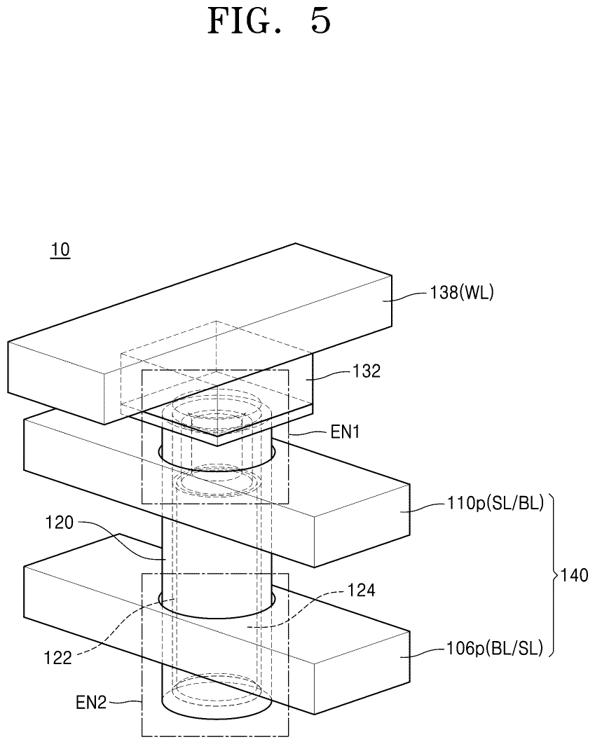

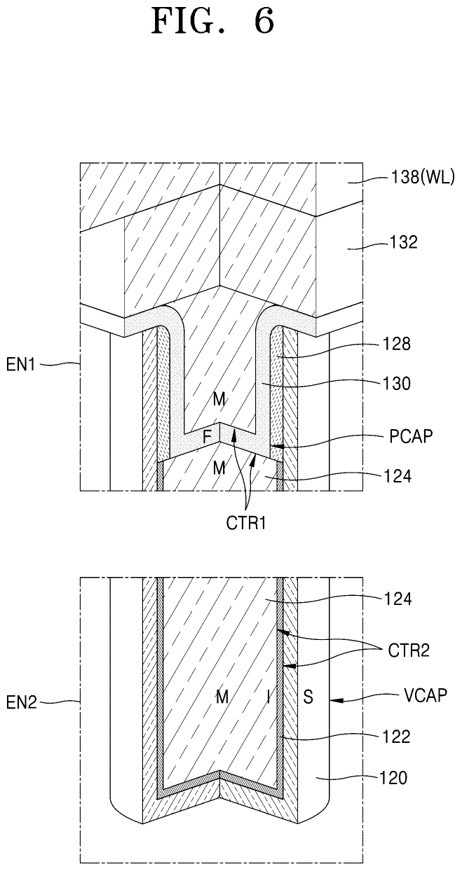

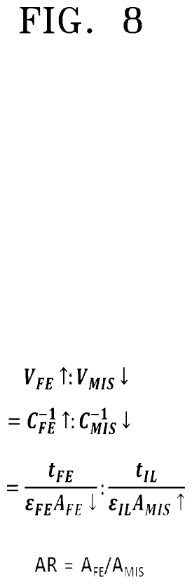

FIG. 5 is a perspective view of the ferroelectric memory device 10 according to some embodiments. FIG. 6 is a partially cut-away enlarged view for illustrating the horizontal capacitor and the vertical capacitor of FIG. 5. FIG. 7 is an equivalent circuit diagram of the horizontal capacitor and the vertical capacitor of FIG. 5. FIG. 8 shows a distribution ratio of a gate voltage applied to the control gate electrode 137 of FIG. 7.

In detail, FIG. 5 is a perspective view of the ferroelectric memory device 10 of FIGS. 2 and 3, and FIG. 6 is an enlarged view of an upper end portion EN1 and a lower end portion EN2 of FIG. 5. The upper end portion EN1 of the ferroelectric memory device 10 may include the inner gate electrode 124, the ferroelectric layer 130, the control gate electrode 132, and the word lines WL 138.

The control gate electrode 132, the ferroelectric layer 130, and the inner gate electrode 124 of the ferroelectric memory device 10 of the upper end portion EN1 may include, as described above, the horizontal capacitor PCAP.

In other words, a control gate electrode (Metal layer), a ferroelectric layer (Ferroelectric material layer), and an inner gate electrode (Metal layer) may constitute a horizontal (flat panel type) MFM capacitor PCAP.

The horizontal MFM capacitor PCAP may be a parallel-plate capacitor formed by the ferroelectric layer 130, and the control gate electrode 132 and the inner gate electrode 124 that are in contact with upper and lower portions of the ferroelectric layer 130. The area of the horizontal MFM capacitor PCAP may be determined by the thickness of the spacer 128 of FIGS. 2 and 3 in contact with a side surface of the ferroelectric layer 130. The term “in contact with” may be used herein to specify an element or layer that is directly on another element or layer without the presence of at least one additional element or layer therebetween.

The lower end portion EN2 of the ferroelectric memory device 10 may include the cylindrical channel layer 120, the gate insulating layer 122, and the inner gate electrode 124. The inner gate electrode 124, the gate insulating layer 122, and the cylindrical channel layer 120 of the lower end portion EN2 of the ferroelectric memory device 10 may constitute, as described above, the vertical capacitor VCAP.

In other words, an inner gate electrode (Metal layer), a gate insulating layer (gate Insulating layer), and a channel layer (polySilicon layer) may constitute a vertical MIS capacitor VCAP.

In the ferroelectric memory device 10, a channel may be formed in the vertical direction due to the cylindrical channel layer 120. The vertical MIS capacitor VCAP may be formed in the vertical direction (i.e., the Z direction of FIGS. 2 and 3) due to the cylindrical channel layer 120. The area of the vertical MIS capacitor VCAP, which is the external area of the cylindrical channel layer 120, may be greater than the area of the horizontal MFM capacitor PCAP.

In the horizontal MFM capacitor PCAP, a first contact area CTR1 of the ferroelectric layer 130, with which the control gate electrode 132 and the inner gate electrode 124 are in contact, may be adjusted through adjustment of the thickness of the spacer 128.

In the vertical MIS capacitor VCAP, a second contact area CTR2 of the gate insulating layer 122, with which the inner gate electrode 124 and the cylindrical channel layer 120 are in contact, may be adjusted through adjustment of the height of the gate insulating layer 122.

The ferroelectric memory device 10, in which the first contact area CTR1 is configured to be smaller than the second contact area CTR2, may increase an electric field applied to the ferroelectric layer 130 and decrease an electric field applied to the inner gate electrode 124, when an operating voltage is applied to the control gate electrode 132.

Accordingly, the ferroelectric memory device 10 may reduce a ratio of the area of the horizontal MFM capacitor PCAP to the area of the vertical MIS capacitor VCAP, without loss of a degree of integration due to the expansion of a channel in the horizontal direction according to the thickness of the spacer 128 adjustment. The ratio of the area of the horizontal MFM capacitor PCAP to the vertical MIS capacitor VCAP is described in detail with reference to FIGS. 7 and 8.

As illustrated in FIG. 7 the horizontal MFM capacitor PCAP and the vertical MIS capacitor VCAP are connected in series to each other. The horizontal MFM capacitor PCAP may have a horizontal capacitance C_{FE}, and the vertical MIS capacitor VCAP may have a vertical capacitance C_{MIS}.

The horizontal MFM capacitor PCAP may have the horizontal capacitance CHE adjusted through the thickness of the spacer 128. The vertical MIS capacitor VCAP may have the vertical capacitance C_{MIS} adjusted through the thickness of the gate insulating layer 122.

As illustrated in FIG. 8, when an operating voltage VG (e.g., gate voltage) is applied through the control gate electrode 132, in order to improve the memory window and increase durability of the ferroelectric memory device 10, a voltage V_{FE} applied to the horizontal MFM capacitor PCAP may need to be increased, and a voltage V_{MIS} applied to the vertical MIS capacitor VCAP may need to be decreased.

When the operating voltage VG (e.g., gate voltage) is applied through the control gate electrode 132, a distribution of voltage applied to the horizontal MFM capacitor PCAP and the vertical MIS capacitor VCAP may be proportional to the inverse C_{FE}⁻¹ of the horizontal capacitance CHE and the inverse C_{MIS}⁻¹ of the vertical capacitance C_{MIS}.

The inverse C_{FE}⁻¹ of the horizontal capacitance CHE may be inversely proportional to an area A_{FE} of the horizontal capacitance C_{FE}, and the inverse C_{MIS}⁻¹ of the vertical capacitance C_{MIS} may be inversely proportional to an area A_{MIS} of the vertical capacitance C_{MIS}. In FIG. 8, ε_{FE} denotes the permittivity of a ferroelectric layer, and t_{FE} denotes the thickness of a ferroelectric layer. En denotes the permittivity of a gate insulating layer, and t_{IL} denotes the thickness of a gate insulating layer.

Accordingly, when the area A_{FE} of the horizontal capacitor PCAP is decreased and the area A_{MIS} of the vertical capacitor VCAP is increased, that is, a ratio AR of the area A_{FE} of the horizontal capacitor PCAP to the area A_{MIS} of the vertical capacitor VCAP is decreased, the voltage V_{FE} applied to the horizontal MFM capacitor PCAP may be increased and the voltage V_{MIS} applied to the vertical MIS capacitor VCAP may be decreased.

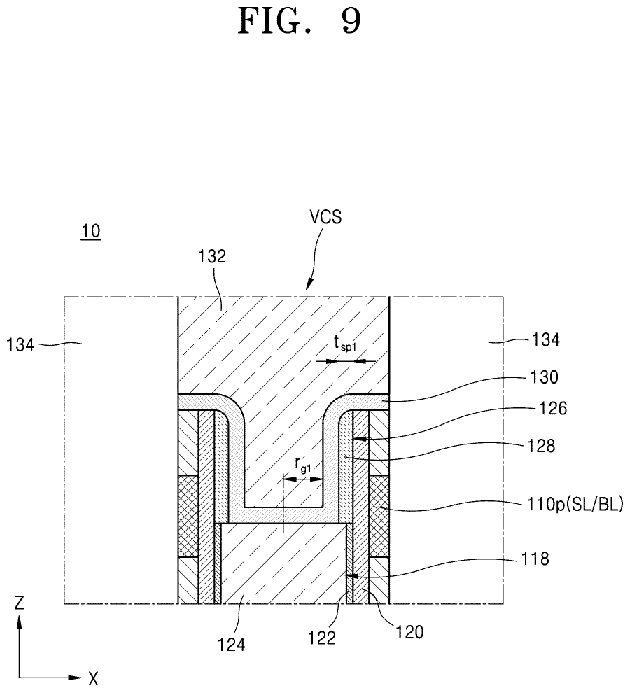

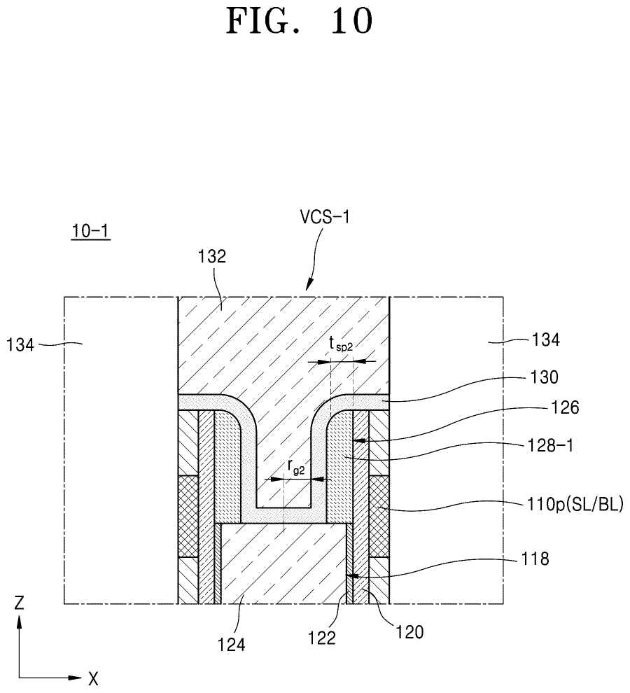

FIGS. 9 and 10 are cross-sectional views for illustrating an adjustment of an area of a horizontal capacitor through an adjustment of a thickness of a spacer of a ferroelectric memory device according to some embodiments.

In detail, in FIGS. 9 and 10, the same reference numerals as those in FIGS. 2 and 3 denote the same elements. In FIGS. 9 and 10, the descriptions in FIGS. 2 and 3 are briefly presented or omitted.

The ferroelectric memory device 10 of FIG. 9 may include the vertical channel structure VCS. The device isolation insulating layer 134 is arranged on opposite sides of the vertical channel structure VCS. The vertical channel structure VCS may include the cylindrical channel layer 120, the gate insulating layer 122, the inner gate electrode 124, the spacer 128, the ferroelectric layer 130, the control gate electrode 132, and the second source and drain layer 110p.

The spacer 128 may be arranged on the side wall of the cylindrical channel layer 120. The spacer 128 may have a first thickness tₛₚ₁, for example, a thickness of tens of nanometers or less. Accordingly, the control gate electrode 132 may have a first radius r_{g1} in the recess hole 126.

A ferroelectric memory device 10-1 of FIG. 10 may include a vertical channel structure VCS-1. The device isolation insulating layer 134 is arranged on opposite sides of the vertical channel structure VCS-1. The vertical channel structure VCS-1 may include the cylindrical channel layer 120, the gate insulating layer 122, the inner gate electrode 124, a spacer 128-1, the ferroelectric layer 130, the control gate electrode 132, and the second source and drain layer 110p.

The spacer 128-1 may be arranged on the side wall of the cylindrical channel layer 120. The spacer 128-1 may have a second thickness tₛₚ₂, for example, a thickness of tens of nanometers or less, which is greater than the first thickness tₛₚ₁. Accordingly, the control gate electrode 132 may have a second radius r_{g2} less than the first radius r_{g1}, in the recess hole 126.

In the ferroelectric memory devices 10 and 10-1, the horizontal capacitance CHE of FIG. 7 of the horizontal capacitor PCAP of FIG. 7 may be adjusted through the adjustment of the thicknesses of the spacers 128 and 128-1. In the ferroelectric memory devices 10 and 10-1, the area of the horizontal capacitor PCAP of FIG. 7 may be adjusted through the adjustment of the thicknesses of the spacers 128 and 128-1.

Accordingly, in the ferroelectric memory devices 10 and 10-1, the ratio AR of an area A_{FE} of FIG. 8 of the horizontal capacitor PCAP of FIG. 7 to the area A_{MIS} of FIG. 8 of the vertical capacitor VCAP of FIG. 7 may be reduced.

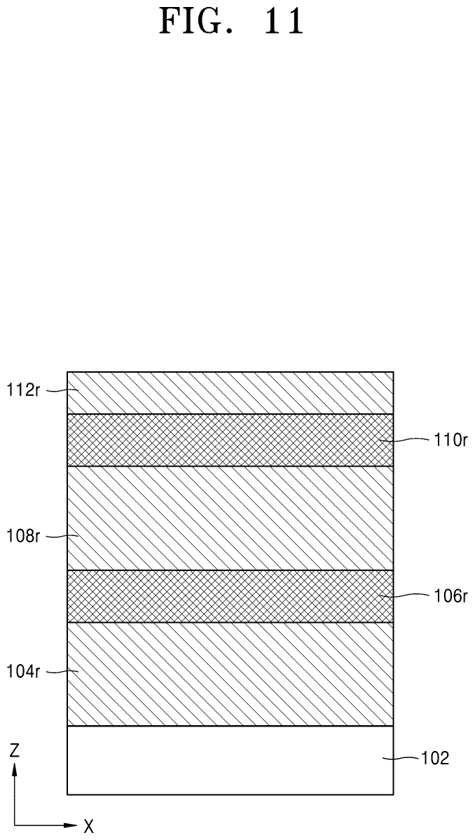

FIGS. 11, 12, 13, 14, 15, 16, and 17 are cross-sectional views for illustrating a method of manufacturing a ferroelectric memory device, according to some embodiments.

In detail, FIGS. 11, 12, 13, 14, 15, 16, and 17 are cross-sectional views for illustrating a method of manufacturing the ferroelectric memory device 10 of FIG. 2. In FIGS. 11, 12, 13, 14, 15, 16, and 17, the same reference numerals as those in FIG. 2 denote the same elements. In FIGS. 11, 12, 13, 14, 15, 16, and 17, the X direction may be a first horizontal direction, and the Z direction may be a vertical direction.

Referring to FIG. 11, a first insulating material layer 104r, a first metal material layer 106r, a second insulating material layer 108r, a second metal material layer 110r, and a third insulating material layer 112r are sequentially formed on and above the semiconductor substrate 102. The first metal material layer 106r is formed between the first insulating material layer 104r and the second insulating material layer 108r. The second metal material layer 110r is formed between the second insulating material layer 108r and the third insulating material layer 112r.

The first insulating material layer 104r, the second insulating material layer 108r, and the third insulating material layer 112r may each be formed to a thickness of tens of nanometers or less, for example, a thickness of 60 nm. The first metal material layer 106r and the second metal material layer 110r may each be formed to a thickness less than the thicknesses of the first insulating material layer 104r, the second insulating material layer 108r, and the third insulating material layer 112r. The first metal material layer 106r and the second metal material layer 110r is formed to a thickness of tens of nanometers or less, for example, a thickness of 10 nm. The first metal material layer 106r and the second metal material layer 110r may correspond to the first source and drain layer 106p and the second source and drain layer 110p, respectively, through the subsequent process.

In some embodiments, the semiconductor substrate 102 may be a semiconductor wafer. The semiconductor substrate 102 may include silicon (Si), for example, crystalline Si, polycrystalline Si, or amorphous Si. In some embodiments, the semiconductor substrate 102 may include a semiconductor element, such as germanium (Ge), or at least one compound semiconductor selected from among silicon germanium (SiGe), silicon carbide (SiC), gallium arsenide (GaAs), indium arsenide (InAs), and indium phosphide (InP).

In some embodiments, the semiconductor substrate 102 may be a silicon-on-insulator (SOI) substrate or a germanium-on-insulator (GOI) substrate. The semiconductor substrate 102 may include a conductive area, for example, an impurity-doped well or an impurity-doped structure.

In some embodiments, the first insulating material layer 104r, the second insulating material layer 108r, and the third insulating material layer 112r may be formed as silicon oxide layers. The first metal material layer 106r and the second metal material layer 110r may each be a metal layer including, for example, TiN, Ti, Al, Au, or W.

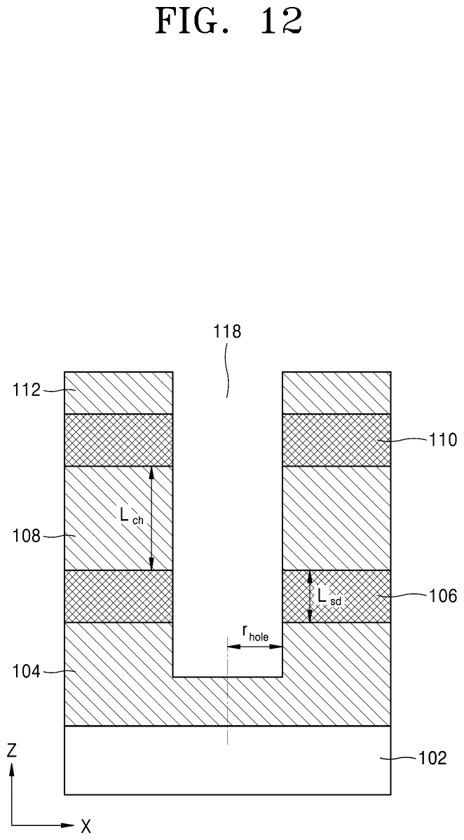

Referring to FIG. 12, the channel hole 118 is formed in the third insulating material layer 112r of FIG. 11, the second metal material layer 110r of FIG. 11, the second insulating material layer 108r of FIG. 11, the first metal material layer 106r of FIG. 11, and the first insulating material layer 104r of FIG. 11. The channel hole 118 is formed by sequentially patterning the third insulating material layer 112r of FIG. 11, the second metal material layer 110r of FIG. 11, the second insulating material layer 108r of FIG. 11, the first metal material layer 106r of FIG. 11, and the first insulating material layer 104r of FIG. 11. A bottom portion of the channel hole 118 is formed inside the first insulating material layer 104r of FIG. 11.

As the channel hole 118 is formed, the third insulating material layer 112r of FIG. 11, the second metal material layer 110r of FIG. 11, the second insulating material layer 108r of FIG. 11, the first metal material layer 106r of FIG. 11, and the first insulating material layer 104r of FIG. 11 may be a third insulating layer 112, a second metal layer 110, a second insulating layer 108, a first metal layer 106, and a first insulating layer 104, respectively. In other words, the third insulating layer 112, the second metal layer 110, the second insulating layer 108, the first metal layer 106, and the first insulating layer 104 may have the channel hole 118 therein.

The channel hole 118 may be a portion where the vertical channel structure described above is to be formed. The vertical channel structure may correspond to a device area. The channel hole 118 may have a radius rₕₒₗₑ. As the channel hole 118 is formed, a length L_{ch} of the second insulating layer 108 between the first metal layer 106 and the second metal layer 110 in the vertical direction (e.g., Z direction) may correspond to a channel length through the subsequent process. A length L_{sd} of each of the first metal layer 106 and the second metal layer 110 in the vertical direction may correspond to a vertical length (i.e., or vertical thickness) of each of the first source and drain layer 106p and the second source and drain layer 110p, through the subsequent process.

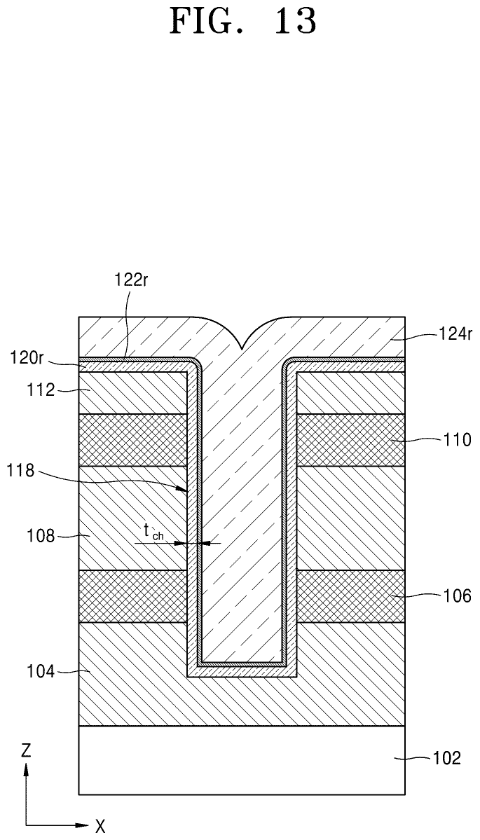

Referring to FIG. 13, a channel material layer 120r is formed on the inner wall and the bottom of the channel hole 118 and on the third insulating layer 112. The channel material layer 120r is formed to a thickness t_{ch} of several nanometers, for example, 5 nm. In some embodiments, the channel material layer 120r is formed as a polysilicon layer. In some embodiments, the channel material layer 120r is formed as an impurity-doped polysilicon layer. A gate insulating material layer 122r is formed on the channel material layer 120r. In some embodiments, the gate insulating material layer 122r is formed as a silicon oxide layer.

An inner gate electrode material layer 124r is formed on the gate insulating material layer 122r to fill the channel hole 118. The inner gate electrode material layer 124r is formed inside the channel hole 118 and the gate insulating material layer 122r on the third insulating layer 112. In some embodiments, the inner gate electrode material layer 124r may be formed as a metal layer including, for example, TIN, Ti, Al, Au, or W.

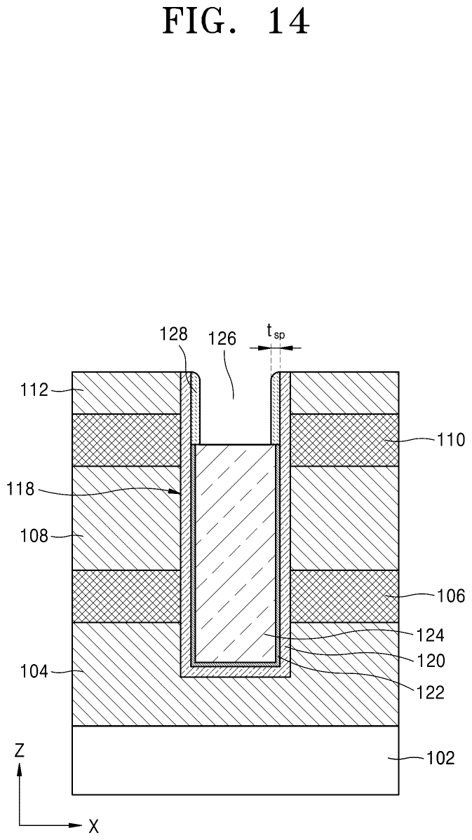

Referring to FIG. 14, the recess hole 126 is formed by etching back the inner gate electrode material layer 124r of FIG. 13 to be lower than an upper surface of the channel hole 118 by using the third insulating layer 112 as an etch stop. As the recess hole 126 is formed, the inner gate electrode material layer 124r of FIG. 13 may become the inner gate electrode 124.

When the inner gate electrode 124 is formed, the gate insulating material layer 122r of FIG. 13 and the channel material layer 120r of FIG. 13 formed on the third insulating layer 112 may be etched. Accordingly, the gate insulating material layer 122r of FIG. 13 and the channel material layer 120r of FIG. 13 become the gate insulating layer 122 and the cylindrical channel layer 120, respectively.

Accordingly, the cylindrical channel layer 120 may be formed inside the channel hole 118. The recess hole 126 may be formed in an upper portion of the channel hole 118 and inside the cylindrical channel layer 120. The gate insulating layer 122 may be formed on the inner wall and the bottom of the cylindrical channel layer 120 within the channel hole 118. The inner gate electrode 124 may be formed on the gate insulating layer 122 to fill a part of the channel hole 118.

Next, the spacer 128 is formed on the inner wall of the recess hole 126 and on the inner gate electrode 124. The spacer 128 is formed on the inner wall of the recess hole 126 recessed in a vertical direction from the upper surface to the lower surface of the cylindrical channel layer 120, and on the inner gate electrode 124. The spacer 128 is formed on the upper surface of the inner gate electrode 124, on the upper surface of the gate insulating layer 122, and on the inner wall of the cylindrical channel layer 120.

The spacer 128 may be formed by forming a spacer material layer on the entire surface of the recess hole 126, the inner gate electrode 124, and the cylindrical channel layer 120 and then anisotropically etching the same. The spacer 128 is formed to a thickness tsp of tens of nanometers or less, for example, 10 nm or less. In some embodiments, the spacer 128 is formed as a silicon oxide layer.

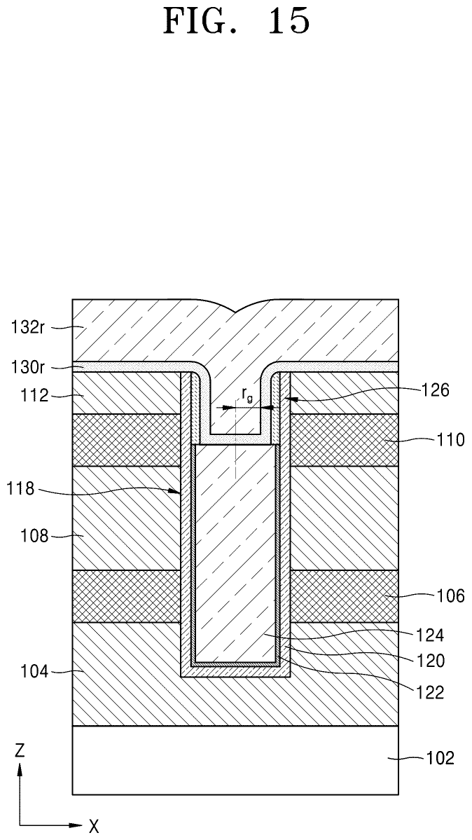

Referring to FIG. 15, a ferroelectric material layer 130r is formed on the side surface and the upper surface of the spacer 128 and on the upper surface of the cylindrical channel layer 120, above the inner gate electrode 124. In some embodiments, the ferroelectric material layer 130r is formed of HfO₂, HfSiO, HfZrO, HfAIO, etc. In some embodiments, the ferroelectric material layer 130r is formed as a perovskite layer, for example, an AMX₃ layer.

Here, A is a large atom with a coordination number of 12, and may be a metal such as Ca, K, Na, Pb, Sr, etc. M is a metal ion with a coordination number of 6. X may be oxygen or a halogen element, such as Cl, Br, or I. In some embodiments, the ferroelectric material layer 130r may be a perovskite layer, such as BaTiO₃, KnbO₃, or PbTiO₃.

A control gate electrode material layer 132r is formed to fill the inside of the recess hole 126 above the ferroelectric material layer 130r. In some embodiments, the control gate electrode material layer 132r may be formed as a metal layer including, for example, TiN, Ti, Al, Au, or W. In some embodiments, the control gate electrode material layer 132r is formed as an impurity-doped polysilicon layer. The control gate electrode material layer 132r formed in the recess hole 126 may have a radius r_{g}.

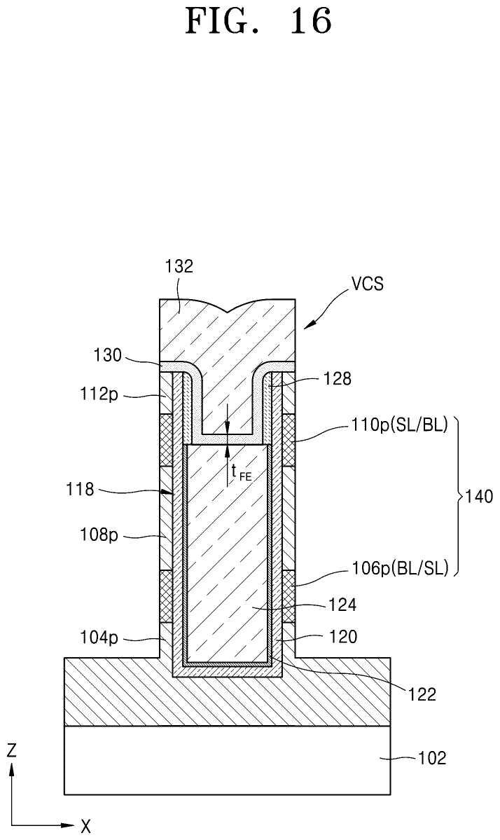

Referring to FIG. 16, a device isolation process may be performed by sequentially etching the control gate electrode material layer 132r of FIG. 15, the ferroelectric material layer 130r of FIG. 15, the third insulating layer 112 of FIG. 15, the second metal layer 110 of FIG. 15, the second insulating layer 108 of FIG. 15, the first metal layer 106 of FIG. 15, and the first insulating layer 104 of FIG. 15.

Accordingly, the control gate electrode material layer 132r of FIG. 15 and the ferroelectric material layer 130r of FIG. 15 may become the control gate electrode 132 and the ferroelectric layer 130, respectively. The ferroelectric layer 130 may be formed on the side surface and the upper surface of the spacer 128 above the inner gate electrode 124. The ferroelectric layer 130 may be formed on the upper surface of the inner gate electrode 124, the side surface and the upper surface of the spacer 128, and the upper surface of the cylindrical channel layer 120. The ferroelectric layer 130 may be formed above the inner gate electrode 124 to a thickness t_{FE} of several nanometers or less, for example, a thickness of 7 nm.

The control gate electrode 132 may be embedded in the recess hole 126 inside the ferroelectric layer 130 above the inner gate electrode 124. The control gate electrode 132 may be formed on the upper surface of the ferroelectric layer 130 inside the recess hole 126, and on the upper surface of the ferroelectric layer 130 formed on the cylindrical channel layer 120.

The third insulating layer 112 of FIG. 15, the second metal layer 110 of FIG. 15, the second insulating layer 108 of FIG. 15, the first metal layer 106 of FIG. 15, and the first insulating layer 104 of FIG. 15 may become the third insulating pattern 112p, the second source and drain layer 110p, the second insulating pattern 108p, the first source and drain layer 106p, and the first insulating pattern 104p, respectively. In some embodiments, the first insulating pattern 104p may be formed by patterning an upper portion of the first insulating layer 104 of FIG. 15.

The first source and drain layer 106p may surround the lower portion of the cylindrical channel layer 120. The second source and drain layer 110p may be apart from the first source and drain layer 106p in the vertical direction (e.g., Z direction) and may surround the upper portion of the cylindrical channel layer 120. The length of the cylindrical channel layer 120 between the first source and drain layer 106p and the second source and drain layer 110p in the vertical direction (e.g., Z direction) may be the vertical channel length L_{CH} of FIG. 12.

The first source and drain layer 106p and the second source and drain layer 110p may be the source and bit lines SL/BL 140 of FIG. 2. The second source and drain layer 110p may be the second source and bit lines SL/BL. The first source and drain layer 106p may be the first source and bit line BL/SL.

For example, when the second source and drain layer 110p is a second source line SL, the first source and drain layer 106p may be a first bit line BL. When the second source and drain layer 110p is a second bit line BL, the first source and drain layer 106p may be a first source line SL. The vertical channel structure VCS is formed through the manufacturing process described above. The vertical channel structure VCS may be one unit memory cell.

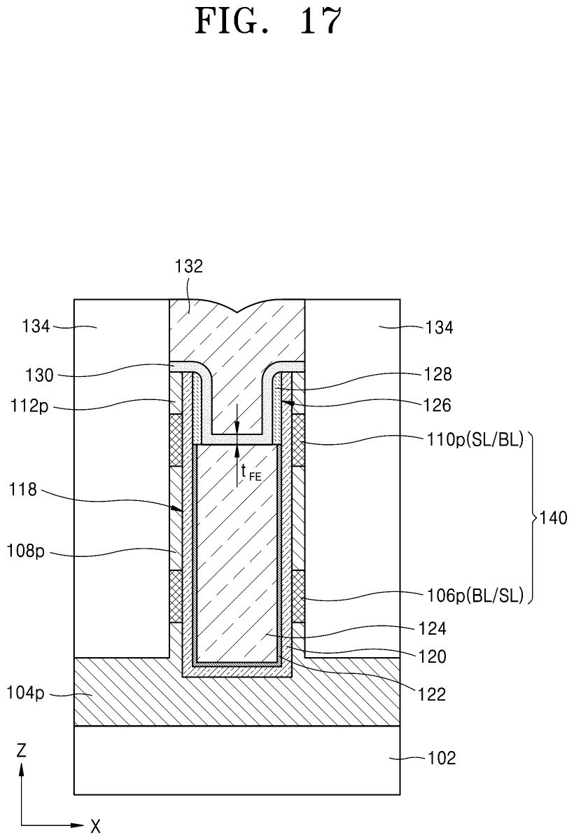

Referring to FIG. 17, the device isolation insulating layer 134 is formed on opposite sides of the vertical channel structure VCS of FIG. 16. The device isolation insulating layer 134 is formed as a silicon oxide layer.

Next, a metal layer, for example, TiN, Ti, Al, Au, or W, is formed on the device isolation insulating layer 134 and the vertical channel structure VCS of FIG. 16. Next, the ferroelectric memory device 10 is manufactured by patterning the metal layer through a photolithographic process, as illustrated in FIG. 2, to form the word lines WL 138.

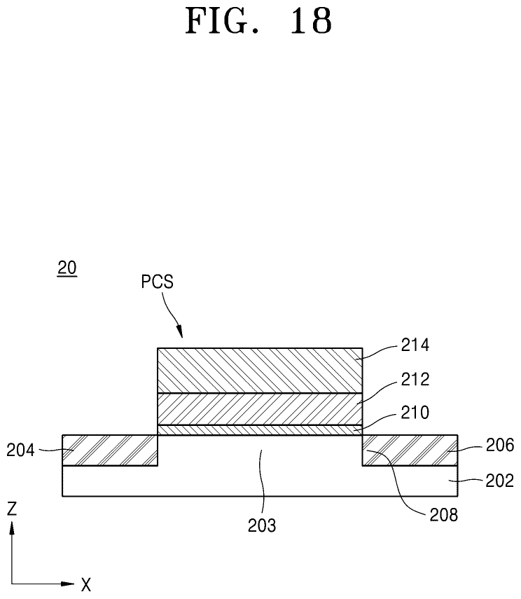

FIG. 18 is a cross-sectional view of a ferroelectric memory device 20 according to a comparative example for comparison with a ferroelectric memory device according to some embodiments.

In detail, the ferroelectric memory device 20 according to a comparative example may include a horizontal channel structure PCS formed on a semiconductor substrate 202. The semiconductor substrate 202 may be a silicon substrate. The horizontal channel structure PCS may include a gate insulating layer 210, a ferroelectric layer 212, and a control gate electrode 214. The gate insulating layer 210 may be formed as a silicon oxide layer. The control gate electrode 214 may be formed as a metal layer.

The ferroelectric memory device 20 according to a comparative example may include a source layer 204 and a drain layer 206 on opposite sides of the horizontal channel structure (PCS) of the semiconductor substrate 202. A channel layer 203 may be arranged on the semiconductor substrate 202 between the source layer 204 and the drain layer 206.

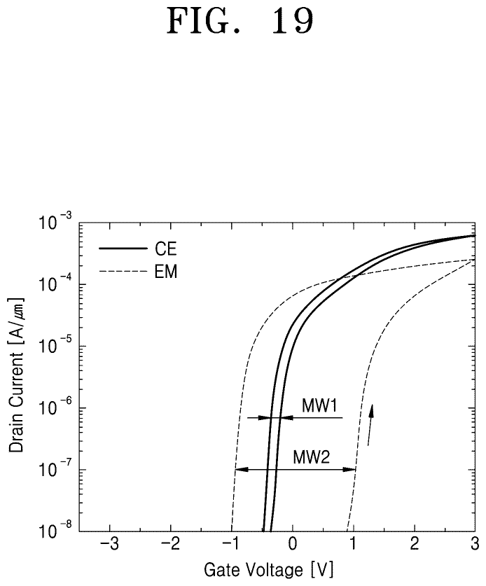

FIG. 19 is a graph for illustrating a memory window of a ferroelectric memory device according to some embodiments.

In detail, the electrical properties of the ferroelectric memory device 10 of FIGS. 2 and 3 according to the inventive concept and the ferroelectric memory device 20 of FIG. 18 according to a comparative example are illustrated in FIG. 19. In FIG. 19, the X-axis denotes a gate voltage applied to a control gate electrode, and the Y-axis denotes a drain current.

As illustrated in FIG. 19, it may be seen that the ferroelectric memory device 10 of FIGS. 2 and 3 according to the inventive concept has a memory window MW2 of about 2 V, as indicated by a reference sign EM, and the ferroelectric memory device 20 of FIG. 18 according to a comparative example has a memory window MW1 of about 0.15 V, which is relatively very low.

The ferroelectric memory device 10 of FIGS. 2 and 3 according to the inventive concept may, as described above, reduce the ratio AR of the area A_{FE} of FIG. 8 of the horizontal capacitor PCAP of FIG. 7 to the area A_{MIS} of FIG. 8 of the vertical capacitor VCAP of FIG. 7 by using the spacer 128 of FIGS. 2 and 3, so as to increase the memory window MW2 as compared with the comparative example.

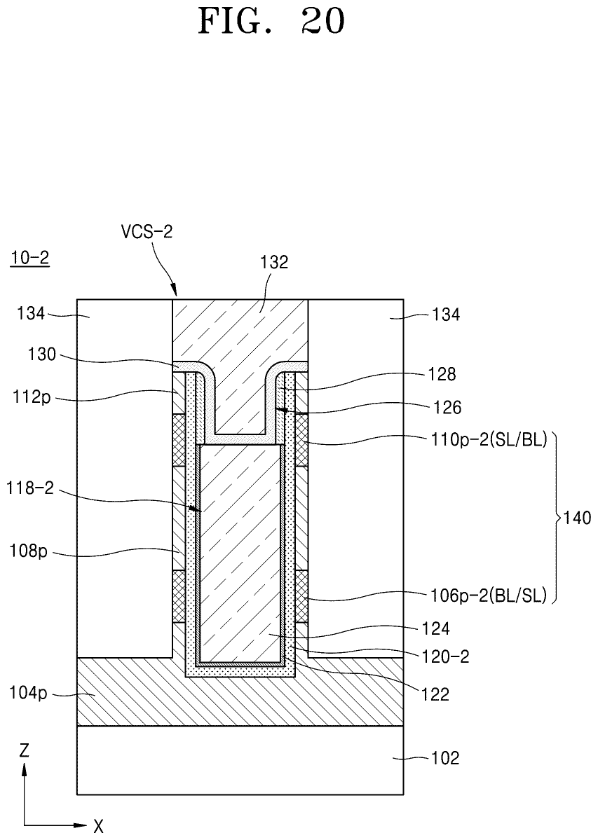

FIG. 20 is a cross-sectional view for illustrating a ferroelectric memory device 10-2 according to some embodiments.

In detail, the ferroelectric memory device 10-2 may be the same as the ferroelectric memory device 10 of FIG. 2, except that the material of a cylindrical channel layer 120-2 constituting a vertical channel structure VCS-2 is different from that of the cylindrical channel layer 120. In FIG. 20, the same reference numerals as those of FIG. 2 denote the same elements. In FIG. 20, the descriptions in FIG. 2 are briefly presented or omitted. In FIG. 20, word lines WL 138 are not illustrated for convenience.

The ferroelectric memory device 10-2 may include the vertical channel structure VCS-2 arranged on the semiconductor substrate 102. The device isolation insulating layer 134 is arranged on opposite sides of the vertical channel structure VCS-2. The vertical channel structure VCS-2 may include the cylindrical channel layer 120-2, the gate insulating layer 122, the inner gate electrode 124, the spacer 128, the ferroelectric layer 130, the control gate electrode 132, the first source and drain layer 106p, and the second source and drain layer 110p.

The cylindrical channel layer 120-2 may have a thickness t_{ch} of several nanometers, for example, 5 nm. In some embodiments, the cylindrical channel layer 120-2 may be formed as an oxide semiconductor layer. In some embodiments, the cylindrical channel layer 120-2 may include IGZO (InGaZnO), IZTO (InZnSnO), IZO (InZnO), etc.

The one or more embodiments described above are intended to exemplify the main concepts of the disclosure, and not limit the inventive concept. It will be understood by one of ordinary skill in the art that various substitutions, amendments, or modifications may be made to the one or more embodiments of the disclosure without departing from the scope of the inventive concept.

While the inventive concept has been particularly shown and described with reference to embodiments thereof, it will be understood that various changes in form may be made without departing from the scope of the following claims.

What is claimed is:

1. A ferroelectric memory device comprising:
a cylindrical channel layer in a channel hole;
a gate insulating layer on an inner wall and a bottom of the cylindrical channel layer;
an inner gate electrode in the channel hole and on the gate insulating layer;
a spacer on the inner gate electrode and on an inner wall of a recess hole, wherein the recess hole extends in a vertical direction from an upper surface towards the bottom of the cylindrical channel layer;
a ferroelectric layer on a side surface and an upper surface of the spacer and on the inner gate electrode;
a control gate electrode in the recess hole and on the ferroelectric layer opposite the inner gate electrode;
a first source and drain layer extending around a lower portion of the cylindrical channel layer; and
a second source and drain layer spaced apart from the first source and drain layer in the vertical direction, and extending around an upper portion of the cylindrical channel layer.

2. The ferroelectric memory device of claim 1, wherein the spacer is on an upper surface of the inner gate electrode, an upper surface of the gate insulating layer, and an inner wall of the cylindrical channel layer.

3. The ferroelectric memory device of claim 1, wherein the recess hole is on the inner gate electrode, in the channel hole and within the cylindrical channel layer.

4. The ferroelectric memory device of claim 1, wherein the ferroelectric layer continuously extends on an upper surface of the inner gate electrode, the side surface and the upper surface of the spacer, and the upper surface of the cylindrical channel layer.

5. The ferroelectric memory device of claim 1, wherein the control gate electrode is on an upper surface of the ferroelectric layer in the recess hole and the upper surface of the ferroelectric layer is on the cylindrical channel layer.

6. The ferroelectric memory device of claim 1, wherein a channel length of the cylindrical channel layer comprises a distance between the first source and drain layer and the second source and drain layer in the vertical direction.

7. The ferroelectric memory device of claim 1, wherein the first source and drain layer and the second source and drain layer each comprise a metal layer.

8. The ferroelectric memory device of claim 1, wherein the cylindrical channel layer comprises a polysilicon layer or an oxide semiconductor layer.

9. A ferroelectric memory device comprising:
a cylindrical channel layer in a channel hole;
a gate insulating layer on an inner wall and a bottom of the cylindrical channel layer;
an inner gate electrode in the channel hole and on the gate insulating layer;
a spacer on the inner gate electrode and on an inner wall of a recess hole, wherein the recess hole extends in a vertical direction from an upper surface towards the bottom of the cylindrical channel layer;
a ferroelectric layer on a side surface and an upper surface of the spacer and on the inner gate electrode;
a control gate electrode in the recess hole and on the ferroelectric layer opposite the inner gate electrode;
a first source and drain layer extending around a lower portion of the cylindrical channel layer; and
a second source and drain layer spaced apart from the first source and drain layer in the vertical direction and extending around an upper portion of the cylindrical channel layer,
wherein the control gate electrode, the ferroelectric layer, and the inner gate electrode comprise a horizontal capacitor,
wherein the inner gate electrode, the gate insulating layer, and the cylindrical channel layer comprise a vertical capacitor, and
wherein the horizontal capacitor is electrically connected in series to the vertical capacitor.

10. The ferroelectric memory device of claim 9, wherein the horizontal capacitor has a horizontal capacitance that is based on a thickness of the spacer, and the vertical capacitor has a vertical capacitance that is based on a height of the gate insulating layer.

11. The ferroelectric memory device of claim 9, wherein, in the horizontal capacitor, a first contact area of the ferroelectric layer is in contact with the control gate electrode and the inner gate electrode, and is based on a thickness of the spacer.

12. The ferroelectric memory device of claim 11, wherein, in the vertical capacitor, a second contact area of the gate insulating layer is in contact with the inner gate electrode and the cylindrical channel layer, and is based on a height of the gate insulating layer.

13. The ferroelectric memory device of claim 12, wherein the first contact area is smaller than the second contact area.

14. The ferroelectric memory device of claim 9, wherein a channel length of the cylindrical channel layer comprises a distance between the first source and drain layer and the second source and drain layer in the vertical direction.

15. The ferroelectric memory device of claim 9, wherein the first source and drain layer and the second source and drain layer each comprise a metal layer, and wherein the cylindrical channel layer comprises a polysilicon layer or an oxide semiconductor layer.

16. A ferroelectric memory device comprising:
a plurality of word lines extending in a first horizontal direction and spaced apart from each other in a second horizontal direction perpendicular to the first horizontal direction;
a plurality of first source and bit lines below the plurality of word lines in a vertical direction, extending in the second horizontal direction, and spaced apart from each other in the first horizontal direction;
a plurality of second source and bit lines between the plurality of word lines and the plurality of first source and bit lines in the vertical direction, extending in the second horizontal direction, and spaced apart from each other in the first horizontal direction; and
a plurality of vertical channel structures in a plurality of intersection areas, respectively, wherein the plurality of intersection areas each comprise an area of overlap between the plurality of word lines, the plurality of first source and bit lines, and the plurality of second source and bit lines,
wherein each of the plurality of vertical channel structures comprises:
a cylindrical channel layer in a channel hole;
a gate insulating layer on an inner wall and a bottom of the cylindrical channel layer;
an inner gate electrode on the gate insulating layer;
a spacer on the inner gate electrode and on an inner wall of a recess hole, wherein the recess hole extends in a vertical direction from an upper surface towards the bottom of the cylindrical channel layer;
a ferroelectric layer on a side surface and an upper surface of the spacer and on the inner gate electrode;
a control gate electrode in the recess hole, on the ferroelectric layer opposite the inner gate electrode, and electrically connected to a respective word line of the plurality of word lines;
a first source and drain layer extending around a lower portion of the cylindrical channel layer and connected to a respective first source and bit line of the plurality of first source and bit lines; and
a second source and drain layer spaced apart from the first source and drain layer in the vertical direction, extending around an upper portion of the cylindrical channel layer, and connected to a respective second source and bit line of the plurality of second source and bit lines.

17. The ferroelectric memory device of claim 16,
wherein the spacer is on an upper surface of the inner gate electrode, an upper surface of the gate insulating layer, and an inner wall of the cylindrical channel layer.

18. The ferroelectric memory device of claim 16, wherein the ferroelectric layer continuously extends on an upper surface of the inner gate electrode, the side surface and the upper surface of the spacer, and the upper surface of the cylindrical channel layer.

19. The ferroelectric memory device of claim 16, wherein the control gate electrode is on an upper surface of the ferroelectric layer in the recess hole and the upper surface of the ferroelectric layer is on the cylindrical channel layer.

20. The ferroelectric memory device of claim 16, wherein a channel length of the cylindrical channel layer comprises a distance between the first source and drain layer and the second source and drain layer in the vertical direction.
